(19) United States
(12) Patent Application Publication
(10) Pub. No.: US 2023/0011266 A1
(43) Pub. Date: Jan. 12, 2023

(54) METHOD FOR FORMING SEMICONDUCTOR STRUCTURE

(71) Applicant: CHANGXIN MEMORY TECHNOLOGIES, INC., Hefei City (CN)

(72) Inventor: Ling-Yi CHUANG, Hefei City (CN)

(73) Assignee: CHANGXIN MEMORY TECHNOLOGIES, INC., Hefei City (CN)

(21) Appl. No.: 17/651,522

(22) Filed: Feb. 17, 2022

Related U.S. Application Data
(63) Continuation of application No. PCT/CN2021/117218, filed on Sep. 8, 2021.

(30) Foreign Application Priority Data
Jul. 12, 2021 (CN) 202110785205.5

(51) Int. Cl. H01L 23/48; H01L 21/768

(52) U.S. Cl. CPC H01L 23/481; H01L 21/76898; H01L 21/76831

(57) ABSTRACT

A method for forming a semiconductor structure includes the following operations. A substrate is provided, and the substrate includes an active surface and a back surface opposite to the active surface. An etching stop layer is formed on the back surface of the substrate. The substrate is fixed onto a first temporary carrier to make the etching stop layer be located between the substrate and the first temporary carrier. The substrate is etched until reaching the etching stop layer to form a via structure penetrating through the substrate.

### CROSS-REFERENCE TO RELATED APPLICATIONS

This is a continuation of International Application No. PCT/CN2021/117218 filed on Sep. 8, 2021, which claims priority to Chinese Patent Application No. 202110785205.5 filed on Jul. 12, 2021. The disclosures of these applications are hereby incorporated by reference in their entirety.

### BACKGROUND

A Through Silicon Via (TSV) technology can achieve a vertical interconnection between chips and between wafers. At present, in the industry, a Backside Via Reveal (BVR) technology is often used to form TSVs.

### SUMMARY

The embodiments of the present disclosure provide a method for forming a semiconductor structure. The method includes the following operations.

A substrate may be provided. The substrate may include an active surface and a back surface opposite to the active surface.

An etching stop layer may be formed on the back surface of the substrate.

The substrate may be fixed onto a first temporary carrier to make the etching stop layer be located between the substrate and the first temporary carrier.

The substrate may be etched until reaching the etching stop layer to form at least one via structure penetrating through the substrate.

### BRIEF DESCRIPTION OF THE DRAWINGS

FIG. 1A is a first process flow diagram of the BVR technology provided in the embodiments of the present disclosure.

FIG. 1B is a second process flow diagram of the BVR technology provided in the embodiments of the present disclosure.

FIG. 1C is a third process flow diagram of the BVR technology provided in the embodiments of the present disclosure.

FIG. 1D is a fourth process flow diagram of the BVR technology provided in the embodiments of the present disclosure.

FIG. 1E is a fifth process flow diagram of the BVR technology provided in the embodiments of the present disclosure.

FIG. 1F is a sixth process flow diagram of the BVR technology provided in the embodiments of the present disclosure.

FIG. 1G is a seventh process flow diagram of the BVR technology provided in the embodiments of the present disclosure.

FIG. 1H is an eighth process flow diagram of the BVR technology provided in the embodiments of the present disclosure.

FIG. 2 is a flow block diagram of a method for forming a semiconductor structure provided in the embodiments of the present disclosure.

FIG. 3A is a first process flow diagram of a method for forming a semiconductor structure provided in the embodiments of the present disclosure.

FIG. 3B is a second process flow diagram of a method for forming a semiconductor structure provided in the embodiments of the present disclosure.

FIG. 3C is a third process flow diagram of a method for forming a semiconductor structure provided in the embodiments of the present disclosure.

FIG. 3D is a fourth process flow diagram of a method for forming a semiconductor structure provided in the embodiments of the present disclosure.

FIG. 3E is a fifth process flow diagram of a method for forming a semiconductor structure provided in the embodiments of the present disclosure.

FIG. 3F is a sixth process flow diagram of a method for forming a semiconductor structure provided in the embodiments of the present disclosure.

FIG. 3G is a seventh process flow diagram of a method for forming a semiconductor structure provided in the embodiments of the present disclosure.

FIG. 3H is an eighth process flow diagram of a method for forming a semiconductor structure provided in the embodiments of the present disclosure.

FIG. 3I is a ninth process flow diagram of a method for forming a semiconductor structure provided in the embodiments of the present disclosure.

FIG. 3J is a tenth process flow diagram of a method for forming a semiconductor structure provided in the embodiments of the present disclosure.

FIG. 3K is an eleventh process flow diagram of a method for forming a semiconductor structure provided in the embodiments of the present disclosure.

### DETAILED DESCRIPTION

Hereinafter, the exemplary embodiments disclosed in the present disclosure will be described in more detail with reference to the drawings. Although the exemplary embodiments of the present disclosure are illustrated in the drawings, it should be understood that the present disclosure may be implemented in various forms and should not be limited by the specific embodiments set forth herein. On the contrary, these embodiments are provided for a more thorough understanding of the present disclosure, and to fully convey the scope of the present disclosure to those skilled in the art.

In the following description, a lot of specific details are given in order to provide a more thorough understanding of the present disclosure. However, it is obvious to those skilled in the art that the present disclosure may be implemented without one or more of these details. In other examples, in order to avoid confusion with the present disclosure, some technical features known in the art are not described. That is, not all the features of actual embodiments are described here. Known functions and structures are not described in detail.

In the drawings, the sizes of a layer, an area and an element and the relative sizes thereof may be exaggerated for clarity. The same reference numerals denote the same elements throughout the present disclosure.

It should be understood that when an element or layer is referred to as being “on”, “adjacent to”, “connected to” or “coupled to” other elements or layers, it means that the element or the layer may be directly on, adjacent to, connected to, or coupled to other elements or layers, or there may be intermediate elements or layers. On the contrary, when an element is referred to as being “directly on”, “directly adjacent to”, “directly connected to” or “directly coupled to” other elements or layers, it means that there are no intermediate elements or layers. It should be understood that although the terms first, second, third, etc. may be used to describe various elements, components, areas, layers, and/or parts, these elements, components, areas, layers, and/or parts should not be limited by these terms. These terms are used merely to distinguish one element, one component, one area, one layer, or one part from another element, another component, another area, another layer, or another part. Therefore, a first element, a first component, a first area, a first layer, or a first part discussed below may be represented as a second element, a second component, a second area, a second layer, or a second part without departing from application teachings of the present disclosure. When the second element, the second component, the second area, the second layer, or the second part is discussed, it does not mean that the first element, the first component, the first area, the first layer, or the first part is necessarily present in the present disclosure.

Spatial relationship terms such as “below”, “under”, “lower”, “beneath”, “above”, and “upper” may be used herein for convenience of describing a relationship between one element or one feature and another element or another feature illustrated in the figures. It should be understood that in addition to the orientation illustrated in the figures, the spatial relationship terms are intended to further include different orientations of devices in use and operation. For example, if the devices in the figures are turned over, elements or features described as being “under”, “beneath” or “below” other elements or features will be oriented to be “on” the other elements or features. Therefore, the exemplary terms “under” and “below” may include both upper and lower orientations. The device may be otherwise oriented (rotated by 90 degrees or in other orientations), and the spatial descriptors used herein may be interpreted accordingly.

The purpose of the terms used herein is only to describe specific embodiments and not is regarded as a limitation of the present disclosure. As used herein, the singular forms “a/an”, “one”, and “the/said” are also intended to include the plural forms as well, unless the context clearly indicates other modes. It should also be understood that when the terms “composed of” and/or “including” are used in this specification, the presence of the features, integers, steps, operations, elements, and/or components is determined, but the presence or addition of one or more other features, integers, steps, operations, elements, components, and/or groups is also possible. As used herein, the term “and/or” includes any and all combinations of the associated listed items.

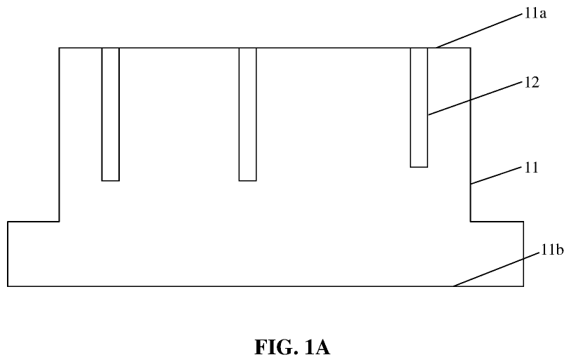

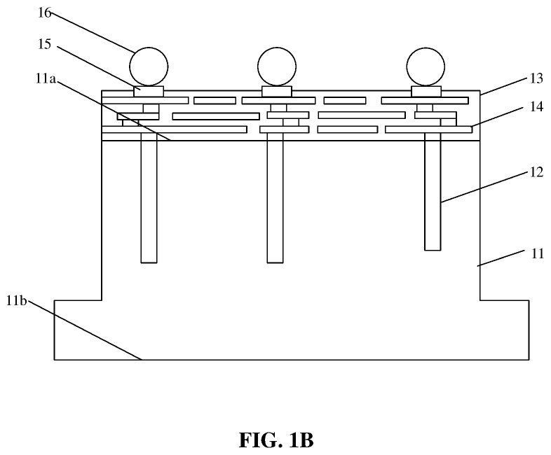

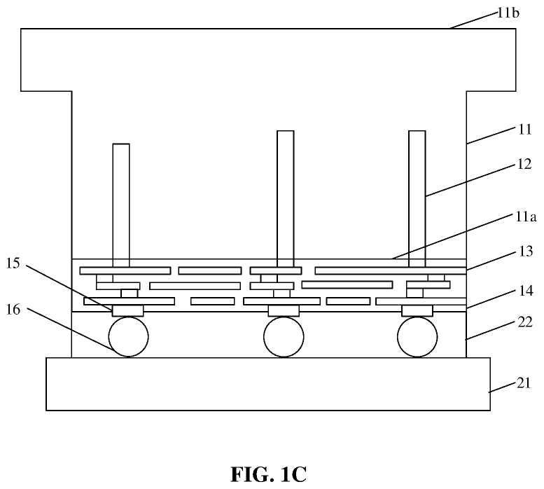

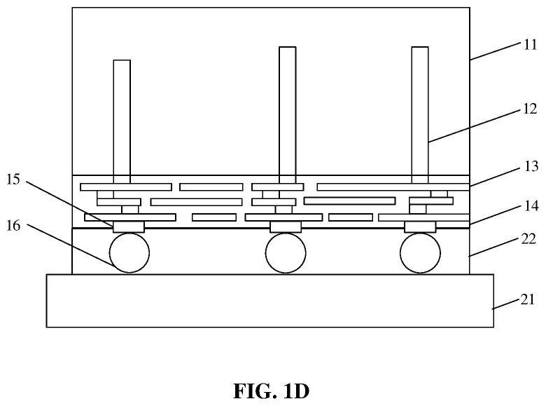

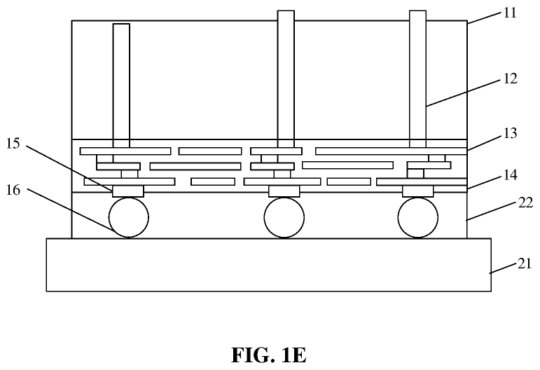

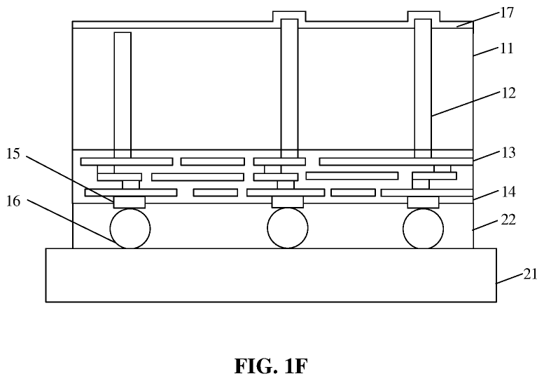

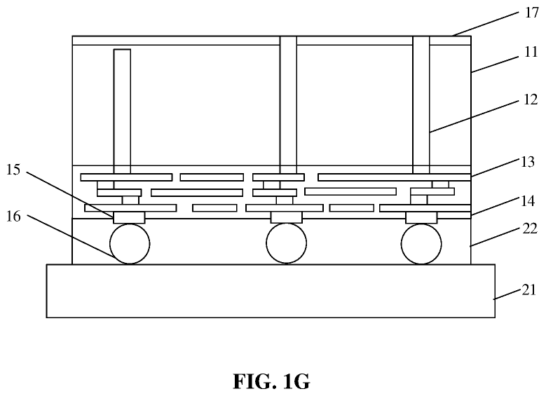

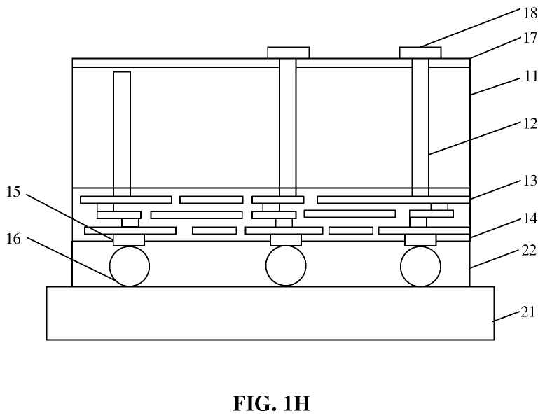

A conductive via can achieve a shortest-distance interconnection between chips and between wafers. The embodiments of the present disclosure provide a BVR technology to prepare the above conductive via, as illustrated in FIG. 1A to FIG. 1H.

Firstly, referring to FIG. 1A, a substrate 11 is provided, the substrate 11 includes an active surface 11a and a back surface 11b opposite to the active surface 11a, the substrate 11 is etched down from the active surface 11a to form at least one via structure, and a conductive material is filled in the via structure to form a conductive via 12.

Referring to FIG. 1B, a dielectric layer 13 and a redistribution layer 14 located in the dielectric layer 13 are formed on the active surface 11a, the redistribution layer 14 is electrically connected to the conductive via 12, and a pad 15 and a bump 16 are formed on the redistribution layer 14.

Referring to FIG. 1C, the substrate 11 is fixed onto a temporary carrier 21 by an adhesive 22. During fixing, the active surface 11a of the substrate 11 faces the temporary carrier 21.

Referring to FIG. 1D, starting from the back surface 11b, the substrate 11 is subjected to a thinning and Chemical Mechanical Polishing (CMP) treatment.

Referring to FIG. 1E, by adopting a deep trenching process a part of the substrate 11 is removed until the conductive via 12 is exposed. Due to inconsistent depths of formed conductive vias 12, some conductive vias 12 cannot be exposed in this operation.

Referring to FIG. 1F, a dielectric layer 17 used for insulation is formed on the substrate 11 and the conductive via 12.

Referring to FIG. 1G, a part of the dielectric layer 17 is removed to expose the conductive via 12.

Referring to FIG. 1H, a pad 18 is formed on the dielectric layer 17, and the pad 18 is electrically connected to the conductive via 12.

However, the process operations of the above BVR technology for manufacturing conductive vias are complex, and the manufactured conductive vias have inconsistent depths, so that the yield of the conductive vias is affected.

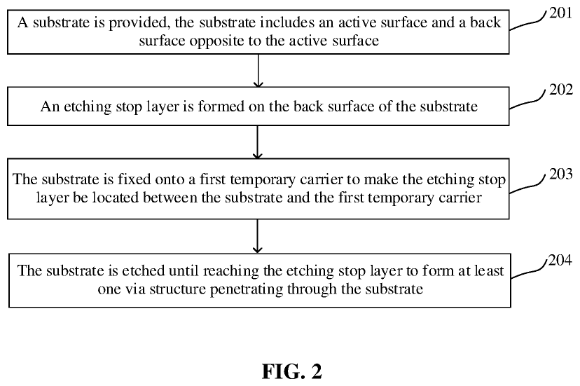

In view of this, the embodiments of the present disclosure further provide a method for forming a semiconductor structure. As illustrated in FIG. 2, the method for forming a semiconductor structure includes the following operations:

In an operation 201, a substrate is provided, and the substrate includes an active surface and a back surface opposite to the active surface.

In an operation 202, an etching stop layer is formed on the back surface of the substrate.

In an operation 203, the substrate is fixed onto a first temporary carrier to make the etching stop layer be located between the substrate and the first temporary carrier.

In an operation 204, the substrate is etched until reaching the etching stop layer to form at least one via structure penetrating through the substrate.

In the embodiments of the present disclosure, before the via structure is formed by etching, the etching stop layer is formed on the back surface of the substrate first, so that the via structure formed by subsequent etching has the same depth. In addition, compared with the BVR technology, the process operations for forming the via structure in the embodiments of the present disclosure are fewer, and the yield is higher.

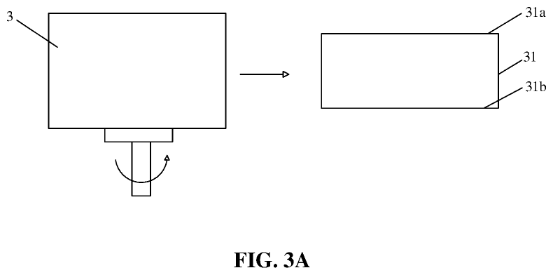

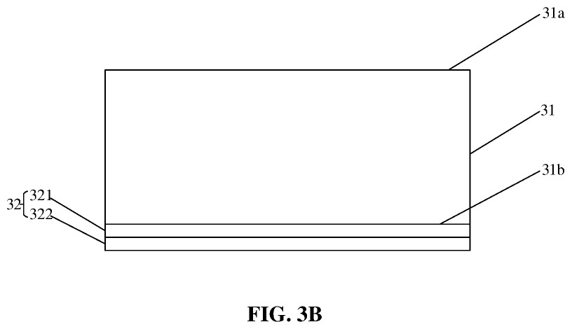

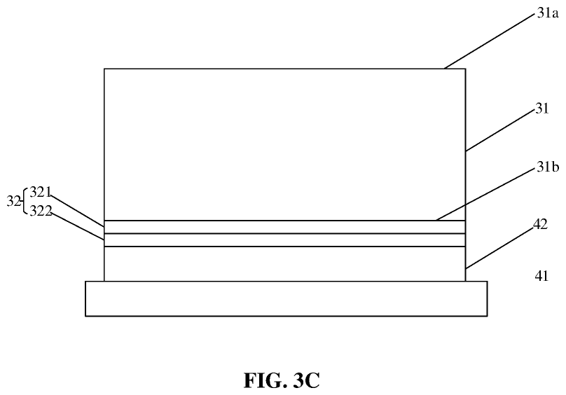

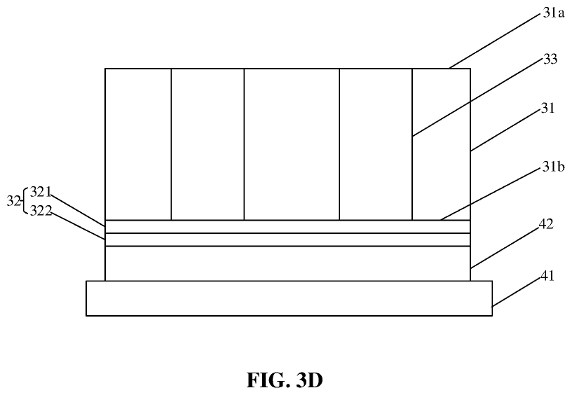

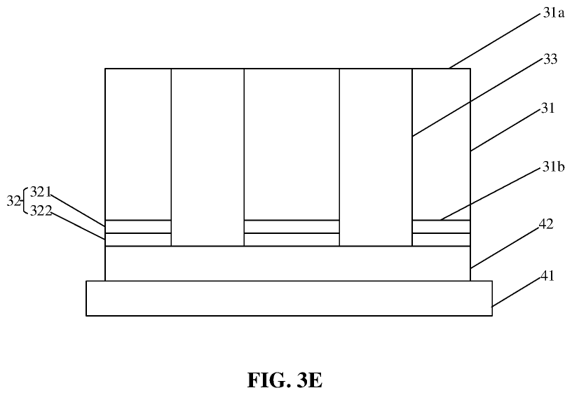

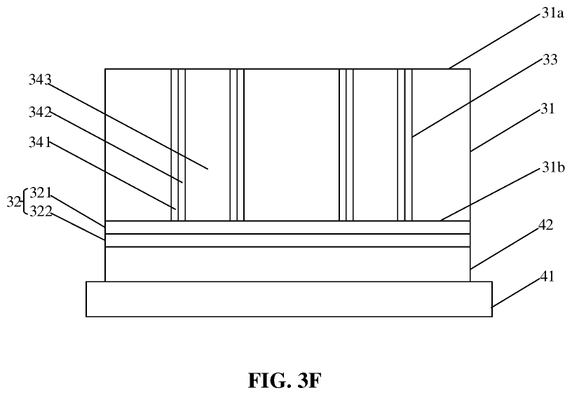

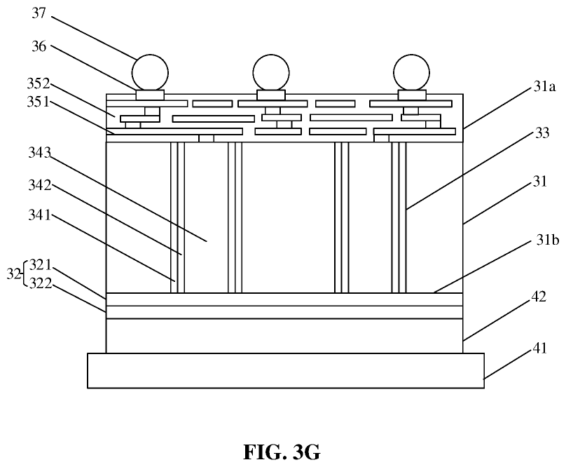

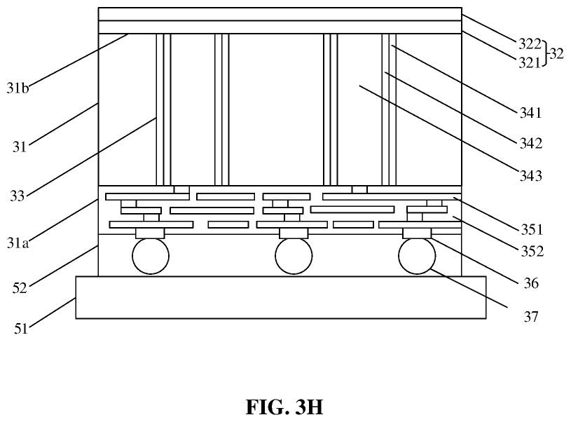

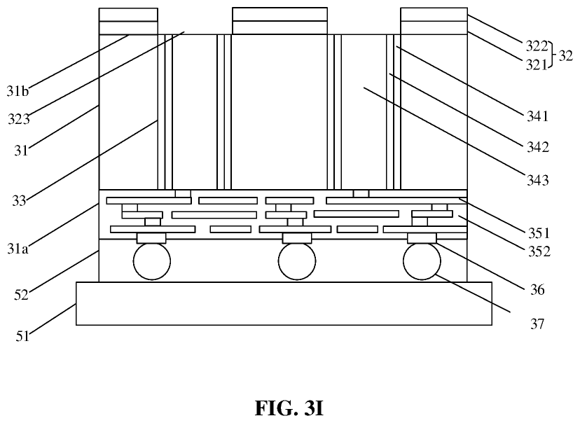

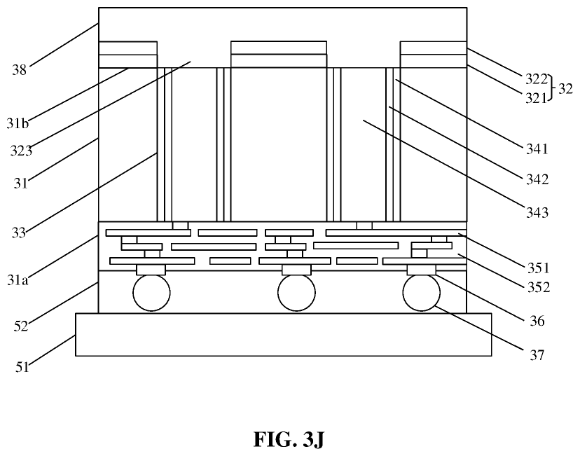

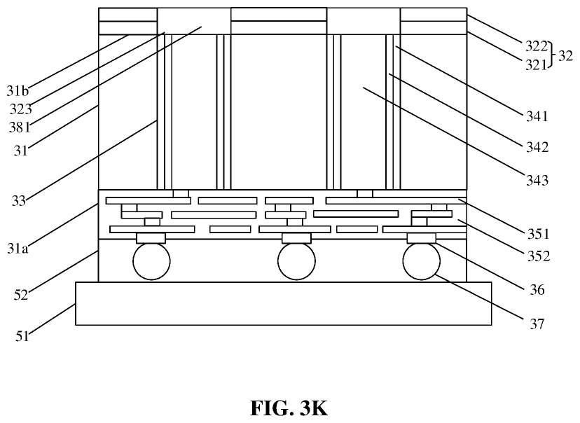

In order to make the above objectives, features and advantages of the present disclosure more obvious and understandable, the method provided in the embodiments of the present disclosure will be further described in detail below with reference to FIG. 3A to FIG. 3K.

Firstly, the operation 201 is performed. As illustrated in FIG. 3A, a substrate 31 is provided, and the substrate 31 includes an active surface 31a and a back surface 31b opposite to the active surface.

The substrate 31 may be a semiconductor substrate. For example, the substrate 31 may be made of single semiconductor materials (such as a silicon (Si) substrate, a germanium (Ge) substrate, etc.), III-V compound semiconductor materials (such as a gallium nitride (GaN) substrate, a gallium arsenide (GaAs) substrate, an indium phosphide (InP) substrate, etc.), II-VI compound semiconductor materials, organic semiconductor materials, or other semiconductor materials known in the art.

In an embodiment, as illustrated in FIG. 3A, the operation of the substrate 31 is provided, includes: a wafer 3 is provided, and the wafer 3 is thinned to obtain the substrate 31. The wafer 3 includes an active surface and a back surface opposite to the active surface, and the substrate 31 can be obtained by thinning the wafer 3 from the back surface. The above thinning treatment may be achieved by a combination of mechanical thinning and chemical mechanical polishing or by chemical corrosion or etching. In a specific embodiment, the wafer 3 is thinned to obtain the substrate 31, and the thickness of the substrate 31 ranges from 50 μm to 250 μm.

Then, the operation 202 is performed. As illustrated in FIG. 3B, an etching stop layer 32 is formed on the back surface 31b of the substrate 31. The etching stop layer 32 is used as a stop layer when via structures are formed by subsequent etching, and can make the formed via structures have the same depth, thereby improving the yield of the via structures. In addition, the etching stop layer 32 also has the same insulating effect as the dielectric layer 17 mentioned in the above embodiments of the present disclosure.

The etching stop layer 32 is configured to stop the etching on the substrate 31, so that the material of the etching stop layer 32 is different from the material of the substrate 31. The etching stop layer 32 may be composed of one material layer or multiple material layers.

In an embodiment, the etching stop layer 32 includes a first sub-layer 321 and a second sub-layer 322. The operation that the etching stop layer 32 is formed on the back surface 31b of the substrate 31, includes the following operations. The first sub-layer 321 is formed on the back surface 31b of the substrate 31; and the second sub-layer 322 is formed on the first sub-layer 321.

In a specific embodiment, a material of the first sub-layer 321 includes silicon nitride, and a material of the second sub-layer 322 includes silicon oxide. In another specific embodiment, the material of the second sub-layer 322 includes silicon oxide, and the material of the first sub-layer 321 includes silicon nitride. The etching stop layer 32 is made of the silicon oxide and/or the silicon nitride. On the one hand, the manufacturing process of the silicon oxide and/or the silicon nitride is relatively conventional and easy to implement. On the other hand, because the silicon oxide and/or the silicon nitride is a common insulating material, by using the silicon oxide and/or the silicon nitride as the etching stop layer 32, the operation of forming an insulating layer or a dielectric layer on the back surface of the substrate 31 after performing the BVR technology in the embodiments of the present disclosure as illustrated in FIG. 1A to FIG. 1H may be omitted, so as to simplify the process for forming the semiconductor structure.

Subsequently, the operation 203 is performed. As illustrated in FIG. 3C, the substrate 31 is fixed onto a first temporary carrier 41 to make the etching stop layer 32 be located between the back surface 31b of the substrate 31 and the first temporary carrier 41. The first temporary carrier 41 is configured to support the substrate 31 to facilitate subsequent etching and film forming processes on the substrate 31. In a specific embodiment, the first temporary carrier 41 includes, but is not limited to, a glass wafer.

In an embodiment, the substrate 31 is fixed onto the first temporary carrier 41 by an adhesive 42.

Then, the operation 204 is performed. As illustrated in FIG. 3D, the substrate 31 is etched until reaching the etching stop layer 32 to form at least one via structure 33 penetrating through the substrate 31.

In the above embodiments of the present disclosure as illustrated in FIG. 1A to FIG. 1H, an etching rate of a central area of the substrate is greater than an etching rate of an edge area of the substrate, so that within the same etching time, the depth of the via structure in the central area is greater than the depth of the via structure in the edge area.

In the embodiments of the present disclosure, the etching stop layer is applied on the back surface of the substrate. Since an etching rate of the etching stop layer is much lower than an etching rate of the substrate, finally, via structures with a same depth may be formed in the substrate.

In an embodiment, the etching is stopped at an interface between the etching stop layer 32 and the substrate 31, as illustrated in FIG. 3D.

In an embodiment, the etching is stopped in the etching stop layer 32 (not illustrated in figures). In a specific embodiment, the etching is stopped in the first sub-layer 321. In another specific embodiment, the etching is stopped in the second sub-layer 322. Stopping the etching in the etching stop layer 32 can further ensure that the via structures formed in the substrate 31 have the same depth.

In an embodiment, the etching is stopped at an interface between the etching stop layer 32 and the adhesive 42, as illustrated in FIG. 3E. In this embodiment, several subsequent operations can be omitted. The operations that can be omitted are as follows. An operation of fixing the substrate 31 onto a second temporary carrier 51 (as illustrated in FIG. 3H), an operation of forming an opening 323 in the etching stop layer 32 (as illustrated in FIG. 3I), and an operation of forming a pad structure 381 in the opening 323 (as illustrated in FIG. 3J and FIG. 3K). Thus, the process for forming the semiconductor structure is greatly simplified. It should be noted that in this embodiment, when the first sub-layer 321 is etched, a lateral etching on the substrate 31 should be avoided; and when the second sub-layer 322 is etched, a lateral etching on the first sub-layer 321 should be avoided. That is, the second sub-layer 322 has a larger etching selection ratio compared with the first sub-layer 321, for example, the etching selection ratio ranges from 50:1 to 200:1, which may be 50:1, 100:1 or 150:1. The first sub-layer 321 also has a larger etching selection ratio compared with the substrate 31, for example, the etching selection ratio ranges from 100:1 to 300:1, which may be 100:1, 200:1 or 300:1. In addition, the etching selection ratio between the first sub-layer 321 and the substrate 31 is greater than the etching selection ratio between the second sub-layer 322 and the first sub-layer 321. The above arrangement can prevent the substrate 31 from being excessively etched and causing problems in the reliability of a chip.

In a specific embodiment, the substrate 31 is etched by Deep Reactive Ion Etching (DRIE).

After the via structure 33 is formed, the method for forming a semiconductor structure further includes the following operations. An insulating layer 341 is formed in the via structure 33, and the insulating layer 341 covers side walls of the via structure 33, as illustrated in FIG. 3F. The insulating layer 341 is configured to electrically isolate the substrate 31 from the conductive material subsequently formed in the via structure 33. A method for forming the insulating layer 341 includes, but is not limited to, chemical vapor deposition and physical vapor deposition.

In an embodiment, the insulating layer 341 includes, but is not limited to, at least one of silicon oxide, silicon nitride or silicon oxynitride.

In an embodiment, the method for forming a semiconductor structure further includes the following operations. A barrier layer 342 is formed in the via structure 33, and the barrier layer 342 covers the insulating layer 341, as illustrated in FIG. 3F. The barrier layer 342 is configured to prevent the subsequently formed conductive material from diffusing to the substrate 31. The barrier layer includes, but is not limited to, at least one of tantalum or titanium. A method for forming the barrier layer 342 includes, but is not limited to, sputtering deposition.

In an embodiment, the method for forming a semiconductor structure further includes the following operations. A first conductive layer 343 is formed in the via structure 33, the first conductive layer 343 completely fills the via structure 33, and the first conductive layer 343 is isolated from the insulating layer 341 by the barrier layer 342, as illustrated in FIG. 3F.

In an embodiment, before the first conductive layer 343 is formed, the method further includes the following operations. A seed layer (not illustrated in figures) is formed on the barrier layer 342. In a specific embodiment, a material of the seed layer includes copper.

In an embodiment, the operation that the first conductive layer 343 is formed in the via structure 33, includes the operation that the first conductive layer 343 is formed on the seed layer by electroplating. The first conductive layer 343 conformally fills the via structure 33.

In an embodiment, the first conductive layer 343 includes at least one of copper or tungsten, but is not limited thereto. Other conductive materials may also be applied to the embodiments of the present disclosure to serve as the first conductive layer 343.

In an embodiment, as illustrated in FIG. 3G, after the first conductive layer 343 is formed, the method further includes the following operations. A redistribution layer 351 is formed on the active surface 31a, and the redistribution layer 343 is electrically connected to the first conductive layer 343; and a conductive bump 37 is formed on the redistribution layer 351.

In a specific embodiment, the method further includes the following operations. A dielectric layer 352 is formed on the active surface 31a, and the redistribution layer 351 is located in the dielectric layer 352.

In a specific embodiment, a material of the redistribution layer 351 includes, but is not limited to, metals such as aluminum and copper; and a material of the dielectric layer includes, but is not limited to, insulating materials such as silicon dioxide, silicon nitride, BCB, and PI.

In a specific embodiment, the operation that a conductive bump 37 is formed on the redistribution layer 351, includes the following operations. A pad 36 is formed on the redistribution layer 351, and a conductive bump 37 is formed on the pad 36.

Referring to FIG. 3H, after the conductive bump 37 is formed, the method includes the following operations. The first temporary carrier 41 is removed; and the substrate 31 is fixed onto a second temporary carrier 51, and the redistribution layer 351 and the conductive bump 37 are located between the substrate 31 and the second temporary carrier 51.

In a specific embodiment, the operation that the substrate 31 is fixed onto the second temporary carrier 51, includes that the substrate 31 is fixed onto the second temporary carrier 51 by an adhesive 52.

As illustrated in FIG. 3I, after the substrate 31 is fixed onto the second temporary carrier 51, surfaces of the etching stop layer 32 are exposed.

In an embodiment, as illustrated in FIG. 3J, the method further includes the following operations. An opening 323 is formed in the etching stop layer 32, and the opening 323 at least exposes the first conductive layer 343 in the via structure 33. In a specific embodiment, the opening 323 also exposes the barrier layer 342.

The etching stop layer in the embodiments of the present disclosure is used as an etching stop layer when the substrate is etched to form a via structure. The etching stop layer in the embodiments of the present disclosure is used as an insulating layer after the via structure is formed, which has the same effect as the dielectric layer 17 in the above embodiments of the present disclosure.

The via structures formed in the embodiments of the present disclosure have the same depth, and the process steps are simpler.

In an embodiment, a shape of the opening 323 includes a rectangle, a circle, an ellipse, a trapezoid, or a triangle.

Referring to FIG. 3J, a second conductive layer 38 is formed, and the second conductive layer 38 fills the opening 323 and covers the etching stop layer 32.

A method for manufacturing the second conductive layer 38 includes, but is not limited to, electroplating or magnetron sputtering.

Referring to FIG. 3K, the second conductive layer 38 covering the etching stop layer 32 is removed to form a pad structure 381 filling the opening 323. In a specific embodiment, the removal is performed by CMP.

In an embodiment, a material of the second conductive layer 38 is the same as a material of the first conductive layer 343, but it is not limited thereto. The material of the second conductive layer 38 may also be different from the material of the first conductive layer 343.

Finally, the adhesive 52 and the second temporary carrier 51 are removed to obtain a semiconductor structure.

The above descriptions are merely the preferred embodiments of the present disclosure and are not intended to limit the scope of protection of the present disclosure. Any modifications, equivalent replacements, improvements and the like made within the spirit and principle of the present disclosure should be included within the scope of protection of the present disclosure.

What is claimed is:

1. A method for forming a semiconductor structure, comprising:
providing a substrate, the substrate comprising an active surface and a back surface opposite to the active surface;
forming an etching stop layer on the back surface of the substrate;
fixing the substrate onto a first temporary carrier to make the etching stop layer be located between the substrate and the first temporary carrier; and
etching the substrate until reaching the etching stop layer to form at least one via structure penetrating through the substrate.

2. The method for forming the semiconductor structure of claim 1, wherein the etching stop layer comprises a first sub-layer and a second sub-layer; and
forming the etching stop layer on the back surface of the substrate comprises: forming the first sub-layer on the back surface of the substrate, and forming the second sub-layer on the first sub-layer.

3. The method for forming the semiconductor structure of claim 2, wherein a material of the first sub-layer comprises silicon nitride, and a material of the second sub-layer comprises silicon oxide; or, a material of the first sub-layer comprises silicon oxide, and a material of the second sub-layer comprises silicon nitride.

4. The method for forming the semiconductor structure of claim 1, wherein providing the substrate comprises: providing a wafer, and thinning the wafer to obtain the substrate.

5. The method for forming the semiconductor structure of claim 1, further comprising:
forming an insulating layer in the via structure, wherein the insulating layer covers side walls of the via structure, and the insulating layer comprises at least one of silicon oxide, silicon nitride, or silicon oxynitride.

6. The method for forming the semiconductor structure of claim 5, further comprising:
forming a barrier layer in the via structure, wherein the barrier layer covers the insulating layer, and the barrier layer comprises at least one of tantalum or titanium.

7. The method for forming the semiconductor structure of claim 6, further comprising:
forming a first conductive layer in the via structure, wherein the first conductive layer completely fills the via structure, the first conductive layer is isolated from the insulating layer by the barrier layer, and the first conductive layer comprises at least one of copper or tungsten.

8. The method for forming the semiconductor structure of claim 7, further comprising:
forming a redistribution layer on the active surface, wherein the redistribution layer is electrically connected to the first conductive layer; and
forming a conductive bump on the redistribution layer.

9. The method for forming the semiconductor structure of claim 8, further comprising:
removing the first temporary carrier; and
fixing the substrate onto a second temporary carrier,
wherein the redistribution layer and the conductive bump are located between the substrate and the second temporary carrier.

10. The method for forming the semiconductor structure of claim 9, further comprising:
forming an opening in the etching stop layer, wherein the opening at least exposes the first conductive layer in the via structure.

11. The method for forming the semiconductor structure of claim 10, further comprising:
forming a second conductive layer, wherein the second conductive layer fills the opening and covers the etching stop layer; and
removing the second conductive layer covering the etching stop layer to form a pad structure filling the opening.

12. The method for forming the semiconductor structure of claim 11, wherein a material of the second conductive layer is the same as a material of the first conductive layer.

13. The method for forming the semiconductor structure of claim 11, wherein a shape of the opening comprises a rectangle, a circle, an ellipse, a trapezoid, or a triangle.
